(19) United States
(12) Patent Application Publication
(10) Pub. No.: US 2010/0206371 A1
(43) Pub. Date: Aug. 19, 2010

(54) REFLECTIVELY COATED SEMICONDUCTOR COMPONENT, METHOD FOR PRODUCTION AND USE THEREOF

(75) Inventors: Stefan Janz, Freiburg (DE); Stefan Reber, Gundelfingen (DE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: FRAUNHOFER-GESELLSCHAFT zur Forderung der angewandten Forschung e.V., Munchen (DE)

(21) Appl. No.: 12/598,351

(22) PCT Filed: May 14, 2008
(86) PCT No.: PCT/EP2008/003877

§ 371 Date: Apr. 23, 2010

(30) Foreign Application Priority Data
May 14, 2007 (EP) 07009628.4

(51) Int. Cl. H01L 31/0232; H01L 21/20; H01L 31/0312

(52) U.S. Cl. 136/256; 438/478; 257/77; 257/E31.023; 257/E31.127; 257/E21.09

(57) ABSTRACT

The invention relates to a reflectively coated semiconductor component which has a semiconductor layer, a functional layer which substantially comprises silicon and carbon, and at least one further layer which substantially comprises silicon and carbon. This further layer functions as reflector for light incident upon the semiconductor component. The invention also relates to a method for the production of semiconductor components of this type. Semiconductor components are used in particular as solar cells or as components of sensors or optical filters.

The invention relates to a reflectively coated semiconductor component which has a semiconductor layer, a functional layer which substantially comprises silicon and carbon, and at least one further layer which substantially comprises silicon and carbon. This further layer functions as reflector for light incident upon the semiconductor component. The invention also relates to a method for the production of semiconductor components of this type. Semiconductor components are used in particular as solar cells or as components of sensors or optical filters.

In the production of highly efficient, thin, crystalline silicon solar cells, the reflection on the rear-side of the solar cell in the longwave range of the light spectrum is of great significance. It is only possible to exploit the full potential of thin solar cells if it can be achieved that the photon stream which has not yet been absorbed during the first irradiation of the thin cell is reflected to a great extent, hence the effective path of the radiated light is extended and hence also the longer wave light is absorbed. According to the design of the solar cell however, in addition to this “reflecting” effect of the rear-side, also other effects are required on the rear-side. Thus there is required, for example with a recrystallised wafer equivalent, a diffusion barrier or, with a wafer-based solar cell, a surface passivation.

In the mentioned cell designs, amorphous silicon carbide (SiC) has been used as diffusion barrier or as passivation already for some time in research. This material is distinguished inter alia in that it has an extreme resistance relative to temperature and many wet-chemical processes. Furthermore, it is used in some cases as a source layer for hydrogen and/or dopant. Amorphous SiC is hence a versatile functional thin layer.

In photovoltaics, layers are required which combine together the properties of high reflectivity, electrical conductivity, surface passivation and/or diffusion barrier. All layers or layer stacks used to date are not able to meet all these properties optimally.

Starting herefrom, it was the object of the present invention to make available semiconductor components which have the corresponding layers with the mentioned properties in combined form. This object is achieved by the semiconductor component with the features of claim 1, by the methods for the production thereof with the features of claims 22 and 23 and the use according to claims 27 to 29. The further dependent claims reveal advantageous developments.

According to the invention, a reflectively coated semiconductor component is provided, which contains a semiconductor layer having a front-side which is orientated towards incident light and a correspondingly oppositely-situated rear-side, the semiconductor layer having on the rear-side a functional layer which substantially comprises silicon and carbon, and a reflector made of at least one further layer which substantially comprises silicon and carbon. The refractive indices of the functional layer and of the reflector, i.e. of the at least one silicon carbide layer or of the layer which substantially comprises silicon and carbon, thereby differ such that light incident upon the semiconductor in the wavelength range of greater than 500 nm is reflected at the reflector. Thus the effective path of the light radiated in the semiconductor layer can at least be doubled.

The reflection properties can as a result be adjusted specifically so that, as a function of the type of functional layer and the refractive index thereof, the refractive index or the refractive indices of the at least one further silicon carbide layer or of the layer which substantially comprises silicon and carbon are adjusted. What is crucial for the effectiveness of the reflection are thereby the differences in the refractive index between the functional layer and the reflector and also the thicknesses of the individual silicon carbide layers of the reflector. The greater the difference in the refractive index, the higher is the maximum reflection. The reflected wavelength range can be adjusted via the layer thicknesses of the individual silicon carbide layers.

Preferably, the reflector reflects light in the wavelength range of 500 nm to 2000 nm. Preferably 60%, particularly preferred 80%, of the light incident upon the semiconductor component is thereby reflected.

Preferably the reflector comprises a system of a plurality of silicon carbide layers, the refractive indices of the individual layers being coordinated to each other such that at least 60%, in particular at least 80%, of the incident light in the wavelength ranges >500 nm is reflected at the reflector.

Basically, the refractive indices of the functional layer and of the layers of the reflector are in the range of 1.4 to 3.8. In the case of a functional layer with a refractive index of 1.4, it is hence preferred to choose a refractive index for the adjacent silicon carbide layer of the reflector which is as high as possible, e.g. 3.8. In this way, a maximum degree of reflection can be achieved. If the reflector comprises a plurality of silicon carbide layers, these can pass through the mentioned refractive index scale of 1.4 to 3.8 in a stepped manner. The best reflection values are obtained when the adjacent silicon carbide layers have a maximum refractive index difference, Alternate layer sequences with the refractive index limiting values 1.4 and 3.8 are hence preferred in these cases.

The at least one silicon carbide layer of the reflector preferably has a thickness which corresponds to a quarter of the wavelength of the radiation which is to be reflected with the shortest wavelength (λₘᵢₙ/4). The at least one layer of the reflector hence has a thickness preferably in the range of 50 nm to 100 μm.

Preferably the at least one layer of the reflector is made of amorphous silicon carbide or substantially contains amorphous silicon carbide.

The carbon content of the silicon carbide layer or of the layer which substantially comprises silicon and carbon is preferably in the range of 5 to 95% at. %. With a carbon content of the silicon carbide layer or of the layer which substantially comprises silicon and carbon of 5% at. %, the refractive index of this layer is approximately 3.6, with a carbon content of the silicon carbide layer of 95% at. %, at approximately 1.7.

Preferably, the functional layer of the semiconductor component has a thickness in the range of 5 nm to 1500 μm. The functional layer thereby preferably comprises amorphous silicon carbide or substantially contains amorphous silicon carbide.

Preferably, the reflector is disposed, at least in regions, on the rear-side, i.e. on the side of the functional side which is orientated away from the light. Likewise, it is also possible that the functional layer is disposed, at least in regions, on the rear-side of the reflector.

The semiconductor layer preferably comprises silicon or substantially contains silicon. In the case of silicon, preferably light in the wavelength range of 500 nm to 1100 nm is reflected by the reflector.

A preferred embodiment of the semiconductor component hereby relates to a wafer-based crystalline silicon solar cell. In this case, the functional layer functions as surface passivation of the semiconductor. The functional layer is thereby disposed at least in regions between semiconductor layer and reflector. Furthermore, the wafer-based solar cell has an electrically contacting layer which is applied on the side of the reflector which is orientated away from the functional layer, i.e. on the free rear-side. This electrically contacting layer is continued via breaks in the functional layer and the reflector, so that an electrical contact to the semiconductor layer is produced.

Another preferred embodiment provides that the semiconductor component is a crystalline silicon thin-film solar cell which is based on a wafer equivalent. In this case, the semiconductor component has a substrate on the rear-side, the functional layer acting as diffusion barrier.

All electrically conductive substrates can be used as substrates. Preferably the substrate is selected from the group comprising crystalline silicon, metallic sheets and ceramic materials. Included herein are e.g. graphite, nitride-based ceramics (TiN, SiN, B) or carbide-based ceramics (SiC, BC, TiC).

A preferred embodiment of the semiconductor component has the following layer sequence:

1) semiconductor layer,

2) functional layer made of silicon carbide as diffusion barrier,

3) reflector made of at least one silicon carbide layer and

4) substrate.

A further preferred embodiment of the semiconductor component has the following layer sequence:

1) semiconductor layer,

2) reflector made of at least one silicon carbide layer and

3) functional layer made of silicon carbide as diffusion barrier,

4) substrate.

According to the invention, a method for the production of a reflectively coated semiconductor component, as was already described, is likewise provided, in which a wafer is introduced into a reaction chamber and, by means of plasma-enhanced chemical vapour deposition (PECVD), thermal CVD or sputtering, there is deposited firstly a silicon carbide layer as functional layer and thereupon at least one further silicon carbide layer as component of a reflector. The refractive indices of the functional layer and of the at least one further silicon carbide layer are thereby coordinated to each other such that reflection of light in the wavelength range of greater than 500 nm of over 60% is effected at the reflector.

According to the invention, a method for the production of a reflectively coated semiconductor component is likewise provided, in which a substrate is introduced into a reaction chamber and, by means of plasma-enhanced chemical vapour deposition (PECVD), thermal CVD or sputtering, there is deposited firstly a reflector made of at least one further silicon carbide layer, a silicon carbide layer as functional layer on the reflector, in particular a diffusion barrier, and a semiconductor layer on the functional layer, the refractive indices of the functional layer and of the at least one further layer of the reflector being coordinated to each other such that reflection of light in the wavelength range of greater than 500 nm of over 60% is effected at the reflector.

Preferably, before the deposition, a plasma cleaning of the surface of the wafer or of the substrate is effected.

For the deposition, preferably methane (CH₄) and silane (SiH₄) are used as process gases. The stoichiometry of the layers and hence the function thereof can be adjusted via the gas flows of the process gases CH₄ and SiH₄.

The stoichiometry can preferably also be adjusted by further process parameters, such as pressure, temperature and plasma power.

The semiconductor components are used in particular in the production of solar cells Likewise, the semiconductor components can be used as components of sensors or optical filters. According to the invention, the use of at least one silicon carbide layer as reflector in a semiconductor component having at least one semiconductor layer and at least one functional layer is provided, the refractive indices of the functional layer and of the at least one silicon carbide layer being coordinated to each other such that over 60% of the light in the wavelength range of greater than 500 nm is reflected at the semiconductor component.

The functional layer thereby serves preferably as surface passivation or diffusion barrier.

Preferably the silicon carbide layer comprises amorphous silicon carbide.

The subject according to the invention is intended to be explained in more detail with reference to the following Figures and examples, without wishing to restrict said subject to the special embodiments shown here.

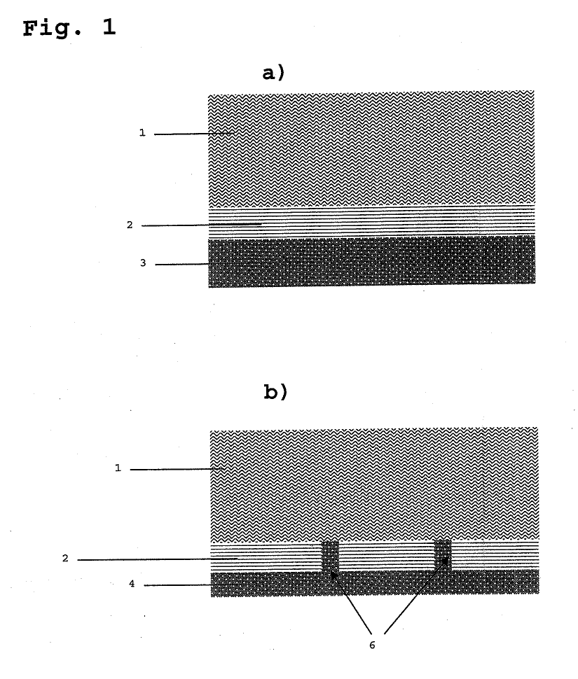

FIG. 1a) shows a recrystallised wafer equivalent known from the state of the art and

FIG. 1b) shows a wafer-based solar cell, as is known from the state of the art.

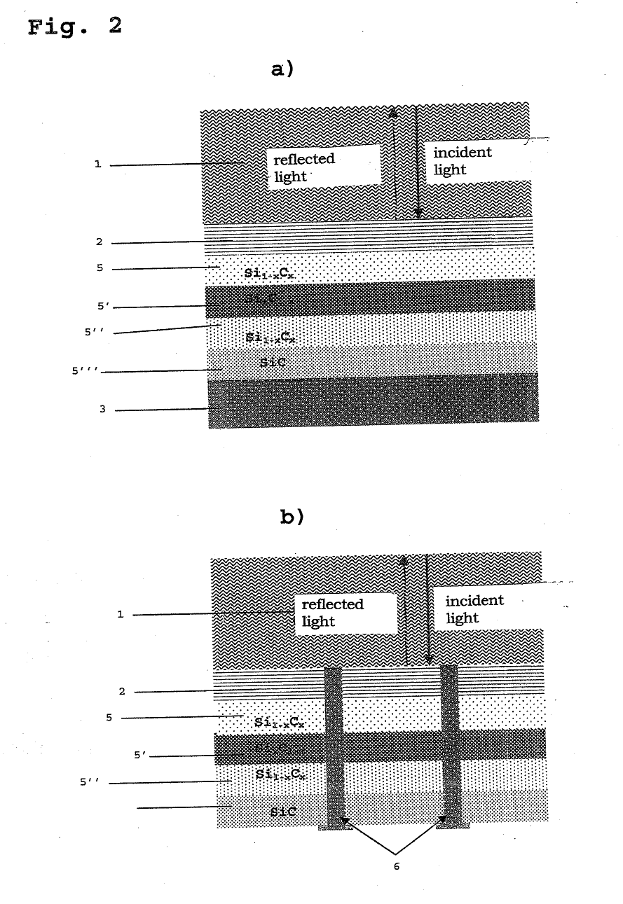

FIG. 2a) shows a wafer equivalent according to the invention and

FIG. 2b) shows a wafer-based solar cell according to the invention.

A recrystallised wafer equivalent is shown in FIG. 1. Coating with a functional layer made of silicon carbide 2 hereby takes place on a substrate 3, this layer serving as diffusion barrier. In turn, a semiconductor layer 1 is applied on the functional layer.

A wafer-based solar cell is illustrated in FIG. 1, with a semiconductor layer 1, generally silicon, said layer being coated on the rear-side with a functional layer made of silicon carbide 2. In turn, a contacting layer 4 is situated on the rear-side thereof, the latter continuing via contact arms 6 through the functional layer up to the semiconductor layer.

The construction of a wafer equivalent known from the state of the art is illustrated in FIG. 2a), with a substrate 3 on which there is deposited a layer system comprising a plurality of silicon carbide layers of different stoichiometries 5 to 5′″ which function as reflectors. A functional layer 2, here a diffusion barrier made of silicon carbide is applied on this layer system. In addition, a semiconductor layer 1 is deposited on the functional layer.

A wafer-based solar cell is illustrated in FIG. 2b), with a semiconductor layer 1 and a silicon carbide layer 2 which serves as surface passivation. In turn, there is applied on the rear-side thereof the layer system comprising a plurality of silicon carbide layers of different stoichiometries 5 to 5′″. Electrical contacts 6 are also included.

### EXAMPLE

### Production of a Functional SiC Layer Combined with a Reflector Layer System in an In Situ Process

Process step 1: the solar cell is introduced into the plasma reactor and subsequently heated to the desired temperature.
Process step 2: the rear-side surface of the solar cell is cleaned by means of plasma.
Process step 3: immediately thereafter, an SiC layer with the function of a surface passivation layer is deposited.
Process step 4: subsequently 5 SiC layers with the refractive indices 2.5, 1.85, 3.6, 1.85, 2.5 with a respective layer thickness of 100 nm are deposited. The methane flow exclusively is thereby altered.

The result of this process sequence is an outstandingly passivated rear-side combined with a reflector which has its maximum in the range between 800 to 1100 nm wavelength.

1. A reflectively coated semiconductor component containing a semiconductor layer having a front-side which is oriented towards incident light and a rear-side, the semiconductor layer having on the rear-side a functional layer which substantially comprises silicon and carbon, and a reflector comprising at least one further layer which substantially comprises silicon and carbon, the refractive indices of the functional layer and of the reflector being coordinated to each other such that light in the wavelength range of greater than 500 nm is reflected at the reflector.

2. The semiconductor component according to claim 1, wherein the reflector reflects light in the wavelength range of 500 nm to 2500 nm.

3. The semiconductor component according to claim 1, wherein over 60% of the light incident upon the semiconductor component is reflected.

4. The semiconductor component according to claim 1, wherein the reflector comprises a system of a plurality of layers, the refractive indices of the individual layers being coordinated to each other such that more than 80% of the light incident upon the semiconductor component in the wavelength range of greater than 500 nm is reflected.

5. The semiconductor component according to claim 1, wherein the refractive indices of the functional layer and of the at least one layer of the reflector is in the range of 1.4 to 3.8.

6. The semiconductor component according to claim 1, wherein the at least one layer of the reflector has an optical thickness which corresponds to λₘᵢₙ/4 of the shortest wave radiation which is to be reflected.

7. The semiconductor component according to claim 1, wherein the at least one layer of the reflector has a thickness in the range of 50 nm to 100 μm.

8. The semiconductor component according to claim 1, wherein the at least one layer of the reflector comprises amorphous silicon carbide or substantially contains the latter.

9. The semiconductor component according to claim 1, wherein adjacent layers of the reflector differ in the carbon content thereof, as a result of which these layers have a different refractive index.

10. The semiconductor component according to claim 1, wherein the functional layer has a thickness in the range of 5 nm to 1500 μm.

11. The semiconductor component according to claim 1, wherein the functional layer comprises amorphous silicon carbide or substantially contains the latter.

12. The semiconductor component according to claim 1, wherein the semiconductor layer comprises amorphous silicon or substantially contains the latter.

13. The semiconductor component according to claim 1, wherein the reflector reflects light in the wavelength range of 500 nm to 1000 nm.

14. The semiconductor component according to claim 1, wherein the semiconductor component is a wafer-based crystalline silicon solar cell and the functional layer functions as surface passivation.

15. The semiconductor component according to claim 14, wherein the functional layer is disposed at least in regions between semiconductor layer and reflector.

16. The semiconductor component according to claim 15, wherein, on the side of the reflector which is oriented away from the functional layer, an electrically contacting layer which produces the electrical contact to the semiconductor layer is applied at least in regions.

17. The semiconductor component according to claim 1, wherein the semiconductor component is a crystalline thin-film solar cell which is based on a wafer equivalent and the semiconductor component has a substrate on the rear-side, the functional layer functioning as diffusion barrier.

18. The semiconductor component according to claim 17, wherein the substrate is electrically conductive.

19. The semiconductor component according to claim 18, wherein the substrate is selected from the group consisting of crystalline silicon and ceramic substrates.

20. The semiconductor component according to claim 17, which includes the following layer sequence:
1) semiconductor layer,
2) functional layer made of silicon carbide as diffusion barrier,
3) reflector made of at least one silicon carbide layer and
4) substrate.

21. The semiconductor component according to claim 17, which includes the following layer sequence:
1) semiconductor layer,
2) reflector made of at least one silicon carbide layer and
3) functional layer made of silicon carbide as diffusion barrier,
4) substrate.

22. A method for the production of a reflectively coated semiconductor component according to claim 1, comprising introducing a wafer into a reaction chamber and, by means of plasma-enhanced chemical vapour deposition (PECVD), thermal CVD or sputtering, depositing firstly a silicon carbide layer as functional layer and thereupon a reflector made of at least one further silicon carbide layer, the refractive indices of the functional layer and of the at least one further layer of the reflector being coordinated to each other such that reflection of light in the wavelength range of greater than 500 nm of over 60% is effected at the reflector.

23. A method for the production of a reflectively coated semiconductor component according to claim 1, comprising introducing a substrate into a reaction chamber and, by means of plasma-enhanced chemical vapour deposition (PECVD), thermal CVD or sputtering, depositing firstly a reflector made of at least one further silicon carbide layer, a silicon carbide layer as functional layer on the reflector and a semiconductor layer on the functional layer, the refractive indices of the functional layer and of the at least one further layer of the reflector being coordinated to each other such that reflection of light in the wavelength range of greater than 500 nm of over 60% is effected at the reflector.

24. The method according to claim 22, which includes plasma cleaning of the surface of the wafer before depositing the silicon carbide layer.

25. The method according to claim 22, which utilizes methane (CH₄) and silane (SiH₄) as process gases.

26. The method according to claim 25, which includes adjusting the stoichiometry of the layers and their function by adjusting the gas flows of the process gases.

27. A solar cell comprising semiconductor component according to claim 1.

28. A component of a sensor or optical filter comprising the semiconductor component according to claim 1.

29-31. (canceled)
